(19) United States
(12) Patent Application Publication
(10) Pub. No.: US 2025/0079125 A1
(43) Pub. Date: Mar. 6, 2025

(54) POWER SUPPLY ARRANGEMENT, PLASMA GENERATING DEVICE AND METHOD FOR CONTROLLING A PLURALITY OF PLASMA PROCESSES

(71) Applicant: TRUMPF Hüttinger GmbH + Co. KG, Freiburg (DE)

(72) Inventors: Jan Peter Engelstaedter, Soelden (DE); Michael Ehinger, Lahr (DE); Felix Reichenbach, Freiburg (DE); Wojciech Gajewski, Warsaw (PL)

(21) Appl. No.: 18/941,029

(22) Filed: Nov. 8, 2024

Related U.S. Application Data
(63) Continuation of application No. PCT/EP2023/062199, filed on May 9, 2023.

(30) Foreign Application Priority Data
May 9, 2022 (DE) 10 2022 111 529.1

(51) Int. Cl. H01J 37/32

(52) U.S. Cl. CPC H01J 37/32357; H01J 37/32899; H01J 37/32935

(57) ABSTRACT

A power supply arrangement for a plurality of plasma generators includes a power input connection, a data connection, and an AC generator stage configured to convert a power from the power input connection into an AC power. The power supply arrangement is configured to ensure that the AC power is supplied to a first load as a first AC power and to a second load spatially remote from the first load as a second AC power, not simultaneously. The power supply arrangement is controllable in such a way that the first AC power and the second AC power have different characteristics in one or more of output current, output voltage, output frequency, output power, or output profile of current and/or voltage, and is configured to output a drive signal for an impedance matching apparatus assigned to one of the first AC power and the second AC power.

### CROSS REFERENCE TO RELATED APPLICATIONS

This application is a continuation of International Application No. PCT/EP2023/062199 (WO 2023/217739 A1), filed on May 9, 2023, and claims benefit to German Patent Application No. DE 10 2022 111 529.1, filed on May 9, 2022. The aforementioned applications are hereby incorporated by reference herein.

### FIELD

Embodiments of the present invention relate to a power supply arrangement for a plurality of plasma generators, to a plasma generating device having such a power supply arrangement, and to a method for controlling a plurality of plasma processes with such a power supply arrangement.

### BACKGROUND

The plasma generating devices may be designed in particular to excite a gas spatially remote from a plasma processing to a gas plasma. Such plasma generators are also known as “remote plasma source.” Such a plasma generator is described, for example, in WO2014/016335 A1 or US2007/0103092 A1.

The power supply arrangement is often offered as a unit with the plasma generator, i.e. the plasma chamber in which the gas plasma is generated. When processing and/or producing materials in a processing chamber, a plurality of such spatially remote gas plasma generators are often required. These can be used, for example, to excite gas, wherein the excited gas is used during processing. They can also be used, for example, to excite gas, wherein the gas emerging from the processing chamber is excited.

Multiple units consisting of power supply arrangement and plasma generator are expensive, and the risk of one of the units failing increases as the number of such units increases.

### SUMMARY

Embodiments of the present invention provide a power supply arrangement for a plurality of plasma generators. Each of the plurality of plasma generators is configured to excite a gas spatially remote from a plasma processing to a gas plasma. The power supply arrangement includes a power input connection for connecting to a supply power, a data connection for connecting to a controller, and an AC generator stage configured to convert a power from the power input connection into an AC power. The power supply arrangement is configured to, via the data connection, ensure that the AC power is able to be supplied to a first load as a first AC power and to a second load spatially remote from the first load as a second AC power. The first load and the second load are not supplied simultaneously. The power supply arrangement is controllable in such a way that the first AC power and the second AC power have different characteristics at least in one or more of output current, output voltage, output frequency, output power, or output profile of current and/or voltage. The power supply arrangement is configured to output a drive signal for an impedance matching apparatus assigned to one of the first AC power and the second AC power.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a first plasma generating device having a first power supply arrangement according to some embodiments;

FIG. 2 shows a second plasma generating device having a second power supply arrangement according to some embodiments;

FIG. 3 shows time diagrams of the output power at a first power output connection according to some embodiments;

FIG. 4 shows time diagrams of the output power at a second power output connection according to some embodiments;

FIG. 5 shows a rectifier bridge circuit according to some embodiments;

FIG. 6 shows a bipolar power converter bridge according to some embodiments;

FIG. 7 shows a first embodiment of a switching unit;

FIG. 8 shows a second embodiment of a switching unit; and

FIG. 9 shows a flowchart for a method sequence according to some embodiments.

### DETAILED DESCRIPTION

Embodiments of the present invention provide a power supply arrangement, a plasma generating device, and/or a method for controlling a plurality of plasma processes in which these disadvantages are overcome.

According to some embodiments, a power supply arrangement for a plurality of plasma generators is disclosed, each of which being designed in particular to excite a gas spatially remote from a plasma processing to a gas plasma, comprising:
a) a power input connection for connecting a supply power;
b) a data connection for connection to a controller,
c) wherein the power supply arrangement is designed to convert power from the power input connection with an AC generator stage into AC power,
d) wherein the power supply arrangement is configured to, via the data connection:
   ensure that the AC power can be supplied as a first AC power to a first load and as a second AC power to a second load spatially remote from the first load, wherein in particular the two loads are not supplied simultaneously, and
   be controllable in such a way that the first AC power and second AC power may have different characteristics at least at one or more of the following control values:
output current,
output voltage,
output frequency,
output power,
output profile of current and/or voltage, and
e) wherein the power supply arrangement is configured to output a drive signal for an impedance matching apparatus, which is assigned to one of the AC powers.

‘Characteristics for control values’ refers to specific predefined values for one or more of the control values.

For example, for the first AC power, the output power may be 3 kW, the output frequency may be 30 kHz, and the output profile of current may be rectangular pulses with a pulse pause ratio of 70% and 100 Hz repetition rate. And for the second AC power, for example, the output power may be 4 kW, the output frequency may be 35 kHz, and the output profile of current, as with the first AC power, may be rectangular pulses with a pulse pause ratio of 70% and 100 Hz repetition rate.

As a control value characteristic, an extreme value, i.e. a value that must not be exceeded, can also be specified additionally or alternatively for one or more of the control values, e.g. a maximum current of 10 A or a minimum power of 100 W.

In at least one of these control value characteristics, the first and the second AC power differ from each other.

In one aspect, the control value characteristics differ in at least two of these control value characteristics, in particular preferably in at least three.

‘Impedance matching apparatus’ refers here to an apparatus which can convert an output impedance, which is connected at its output e.g. in the direction of the load, such that a specifiable impedance can be set at its input. There are many types of impedance matching apparatuses. Descriptions of these can be found, for example, in WO 2016/177766 A1, WO 2017/072087 A1, WO 2019/185423 A1, WO 2021/255250 A1. Often they have both variable and non-variable reactances, i.e. inductances and capacitances. Impedance-changing elements such as transmission lines, resistors, transformers, balun, couplers are also known. The variable elements can be electronically controllably variable. For example, vacuum capacitors can be modifiable using motors, or reactances can be connectable and disconnectable.

The AC generator stage refers to an electronic circuit that is configured to convert an initial electrical power, e.g. DC power, into AC power. The AC power is characterized by the fact that the voltage and the current change their sign periodically. Current and voltage can have different profiles. The voltage and/or the current can be approximately sinusoidal, or approximately rectangular. In the latter case, it is often referred to as a bipolar voltage generator stage. Such an AC generator stage often has a bridge circuit of switching elements, in particular transistors, preferably MOSFET or IGBT.

In one aspect, the power supply arrangement also comprises:
a) a first power output connection for supplying the first AC power to the first load,
b) a second power output connection for supplying the second AC power to the second load spatially remote from the first load.

In one aspect, the power supply arrangement further comprises a switching unit, which is in particular part of the power supply arrangement, wherein the power supply arrangement is configured to be controllable via the data connection in such a way that the switching unit can connect the AC power generated by the AC generator stage in each case to one of the power output connections and/or loads, and can in the process set the different characteristics of the respective AC power.

‘Switching unit’ is here understood to mean an electronic component which is configured to transmit an electrical signal in a first setting from one of its contacts to a second of its contacts and to impede this transmission, in particular prevent it, in a second setting. Advantageously, the switching unit in the second setting can transmit the electrical signal in the second position from the first contact to a third contact and impede this transmission, in particular prevent it, in the first setting. A switching unit can be a transistor, in particular a power transistor, advantageously an IGBT or MOSFET. Other embodiments such as PIN diodes or electromechanical switches are also conceivable.

In one aspect, a power supply arrangement for a plurality of plasma generators, each of which is specifically designed to excite a gas spatially remote from a plasma processing to a gas plasma, is disclosed, comprising:
a) a power input connection for connecting a supply power;
b) a data connection for connection to a controller which may be arranged in particular within or outside the power supply arrangement,
c) wherein the power supply arrangement is designed to convert power from the power input connection with an AC generator stage into a first and a second AC power,
d) a first power output connection for supplying the first AC power to a first load,
e) a second power output connection for supplying the second AC power to a second load spatially remote from the first load,
f) wherein the power supply arrangement is configured to be controllable via the data connection in such a way that the first and the second AC power may have different characteristics at least at one or more of the following control values:
output current,
output voltage,
output frequency,
output power,
output profile of current and/or voltage, and
g) wherein the power supply arrangement is configured to output a drive signal, in particular a plurality of drive signals, for a, in particular for each, impedance matching apparatus which is assigned to one of the AC powers.

Thus, a plurality of plasma processes or a plurality of plasma generators can be operated with one power supply arrangement. This increases reliability and significantly reduces costs. Since one or more drive signal(s) for the impedance matching apparatus(es) assigned to the plasma generator(s) is/are provided, they can also be provided individually adapted for the respective AC power at the respective plasma generator.

In one aspect, the power supply arrangement may comprise one, in particular a plurality of, switching unit(s), wherein the power supply arrangement is configured to ensure via the data connection that the switching unit(s) connects the AC power generated by the AC generator stage to in each case one of the power output connections, and the power supply arrangement may further be configured to set the different characteristics of the respective AC power. Thus, the one power supply arrangement can supply the individual plasma generators with one AC generator stage. This significantly saves costs.

In one aspect, one, in particular a plurality of, switching unit(s) may be arranged outside the power supply arrangement, wherein the power supply arrangement is configured to be able to control it or them via the data connection in such a way that the switching unit(s) connect(s) the AC power generated by the AC voltage generating stage to in each case one of the power output connections and in the process the different characteristics of the respective AC power can be set. Thus, the one power supply arrangement can supply the individual plasma generators with one AC generator stage. This significantly saves costs and is also adaptable with great flexibility to the particular application.

A connecting line for transmitting the AC power with a length of 1 m or more, in particular 3 m or more, may be arranged between the impedance matching apparatus(es) and a power supply arrangement. This makes the use of the power supply arrangement flexible and therefore cost-effective.

In one aspect, the power supply arrangement may be designed so that the rated power of all AC powers suppliable to the loads, in particular those that may be output, added together are greater than the rated power of the AC power generator stage. Thus, an AC generator stage with a relatively low rated power can be used to supply a plurality of plasma generators, all of which individually do not require more rated power than the AC generator stage can provide in terms of rated power, but, at the same time, all of which added together would require a significantly higher rated power. This works because the plasma generators can be supplied sequentially in time, i.e. never all at the same time.

In one aspect, the power supply arrangement may be configured to output different drive signals for a plurality of impedance matching apparatuses, each of which is assigned to one of the AC powers.

In one aspect, the power supply arrangement may be configured to receive one and/or more plasma signals, in particular one and/or more plasma voltages, from one of the plasma generators.

‘Plasma signal’ refers to a signal that is detected, i.e., measured, in or in the immediate vicinity of the generated plasma. This can be a signal, for example, that is measured on the winding side of the excitation transformer which is used to excite the plasma. It can also be a measured light signal, an electromagnetic wave in the non-visible range, e.g. UV, X-ray range, an electric or magnetic field, a noise, vibration, ultrasonic signal. It is preferred to have a plasma voltage which can be measured in particular at or on the winding side of the excitation transformer.

In one aspect, the power supply arrangement may be configured to assign one or more of the transmitted plasma signals to the characteristics of the AC powers, in particular to set the characteristics of the AC powers in dependence on the respective plasma signals. This allows all plasma generators to be controlled very precisely and reliably individually by a power supply arrangement.

In one aspect, the power supply arrangement may be configured to receive one and/or more voltages and/or currents from a current measurement sensor and/or voltage measurement sensor, which is arranged and configured to measure current and/or voltage of the AC power. In particular, the power supply arrangement may also be configured to assign one or more of the transmitted voltages and/or currents to the characteristics of the AC powers, in particular to set the characteristics of the AC powers in dependence on the respective voltages and/or currents. This allows all plasma generators to be controlled very precisely and reliably individually by a power supply arrangement.

In one aspect, the power supply arrangement may be configured to receive one and/or more voltages and/or currents from a current measurement sensor and/or voltage measurement sensor which is arranged and configured to measure current and/or voltage in or at an impedance matching apparatus. In particular, the power supply arrangement may also be configured to assign one or more of the transmitted voltages and/or currents to the characteristics of the AC powers, in particular to set the characteristics of the AC powers in dependence on the respective voltages and/or currents. This allows all plasma generators to be controlled very precisely and reliably individually by a power supply arrangement.

In one aspect, the controller can be integrated into the power supply arrangement. This enables further cost savings, and thus all plasma generators can be controlled very precisely and reliably individually by a power supply arrangement.

In one aspect, a plasma generating device may comprise:
a) a power supply arrangement as described above, and
b) a plurality of plasma generators, which are connected to the power supply arrangement, in particular to the power output connections thereof, and which may be operated according to the control value characteristics.

In one aspect, the plasma generating device may have a first transformer arrangement, in particular one transformer arrangement for each plasma generator, for coupling the AC power to the load, wherein preferably the transformer arrangement is arranged in the immediate vicinity of the load. This enables further cost savings, and thus all plasma generators can be controlled very precisely and reliably individually by a power supply arrangement. ‘Transformer arrangement’ refers to an electrical inductive component which has a first winding and a second winding and can transfer an alternating power applied to the first winding (primary winding) to the second winding (secondary winding). There are many different design options for such a transformer arrangement, for example the windings can be wound on a magnetic core, they can be arranged planar on a circuit board, or represent a combination of both designs, with even further variants being possible. A possible second ‘winding’ can also be the generated plasma itself. An example of such a transformer arrangement is disclosed, for example, in U.S. Pat. No. 9,368,328 B2 as “transformer 35.”

In one aspect, the plasma generating device may have an impedance matching apparatus, in particular a plurality of impedance matching apparatuses, wherein preferably one impedance matching apparatus is arranged between the power supply arrangement and the plasma generator. This enables further cost savings, and thus all plasma generators can be controlled very precisely and reliably individually by a power supply arrangement.

In one aspect, the plasma generating device may have a connecting line with a length of 1 m or more, in particular 3 m or more, between the impedance matching apparatus and the power supply arrangement. This makes the plasma generating device flexible to use.

In one aspect, the plasma generating device can have a plasma generator for the post-treatment of a gas that exits from a plasma processing device. In one aspect, the plasma generating device can have a plasma generator for the pretreatment of a gas that is introduced into a plasma processing device. In particular, the plasma generating device can have both plasma generators.

In one aspect, the impedance matching apparatus(es) may comprise one or more of the following components:
a) inductors,
b) capacitors,
   wherein the inductors and/or capacitors can be settable controlled by a signal connected to the data connection. This enables further cost savings, and thus all plasma generators can be controlled very precisely and reliably individually by a power supply arrangement.

In one aspect, one, in particular a plurality of the plasma generator(s) may be designed to excite a gas spatially remote from a plasma processing to a gas plasma. That is to say, they can be used advantageously as so-called remote plasma sources.

In one aspect, a method for controlling a plurality of plasma processes, each of which is specifically designed to excite a gas spatially remote from a plasma processing to a gas plasma, may be provided, comprising the following steps:
a) supplying electrical supply power to a power supply arrangement,
b) converting the electrical supply power into a first AC power and supplying the first AC power to a first load of a first plasma generator,
c) converting the electrical supply power into a second AC power and supplying the second AC power to a second load of a second plasma generator,
   wherein in particular steps b) and c) are not effected at the same time,
d) controlling the AC powers according to different characteristics at one or more of the following control values:
output current,
output voltage,
output frequency,
output power,
output profile of current and/or voltage, and
e) generating and outputting a drive signal for an impedance matching apparatus which is assigned to one of the AC powers.

Thus, a plurality of plasma processes or a plurality of plasma generators can be operated with one power supply arrangement. This increases reliability and significantly reduces costs. Since one or more drive signal(s) for the impedance matching apparatus(es) assigned to the plasma generator(s) is/are provided, they can also be provided individually adapted for the respective AC power at the respective plasma generator. All previously described features of the apparatus(es) can also develop the method accordingly.

In one aspect, the method can supply a plurality of AC powers to a respective load of an associated plasma generator, wherein the AC powers are not supplied to the loads at the same time, and each load is operated with its associated control characteristic, and generate and output in particular a plurality of drive signals for impedance matching apparatuses which are assigned to one of the AC powers.

In one aspect, the first and/or second AC power can be transmitted in each case via a connecting line with a length of 1 m or more, in particular 3 m or more. This makes the method very flexible and therefore cost-effective.

In one aspect, a computer program product may be provided for controlling a previously described power supply arrangement, in particular for the features g) and f), and/or for the method steps d) and e).

In one aspect, a non-volatile storage medium may be provided with instructions stored on it for execution with a processor or for configuring a programmable logic module for performing the control of a previously described power supply arrangement, in particular for the features g) and f), and/or for the method steps d) and e).

Further features and advantages of the embodiments of the invention are evident from the following detailed description, with reference to the figures of the drawing. The features shown there are to be understood as not necessarily to scale and are illustrated in such a way that the special features according to embodiments of the invention can be made distinctly visible. The various features may be realized in each case individually by themselves or as multiples in any desired combinations.

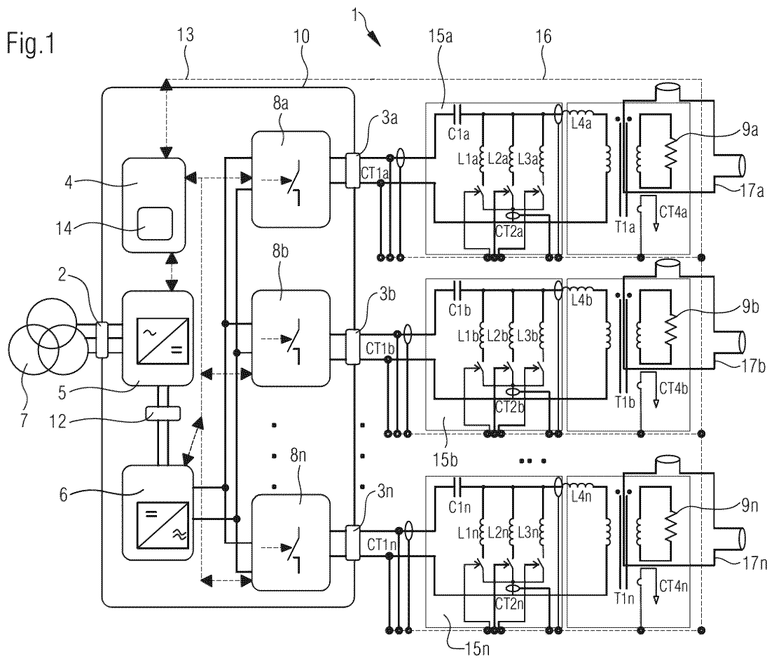

FIG. 1 shows a first plasma generating device 1 comprising a first power supply arrangement 10 and, for example, three plasma generators 17a, 17b, . . . 17n. The plasma generating units 17a, 17b, 17n each comprise a load 9a, 9b, . . . 9n, which are each connected via an impedance matching apparatus 15a, 15b, . . . 15n to a power output connection 3a, 3b, . . . 3n.

For clarity, only three plasma generating units 17a, 17b, 17n each with an impedance matching apparatus 15a, 15b, . . . 15n were shown. Of course, more than three such devices may be used. This is indicated by the three dots for example between the power output connections 3b and 3n. Measurement sensors CT1a, CT1b, . . . . CT1n, e.g. for current and/or voltage measurements, are located at the power output connections 3a, 3b, . . . 3n. The signals determined there are fed via a data bus 16 to a data connection 13, which is connected to the controller 4. Measurement sensors for frequency, phase, power, in particular forward and/or reflected power are also possible here.

The loads 9a, 9b, . . . 9n are in particular so-called ‘remote plasma sources,’ RPS. These are special plasma generators 17a, 1b, . . . 17n, which are configured to excite a gas spatially remote from a plasma processing to a gas plasma. Transformer arrangements T1a, T1b, . . . T1n are advantageously used for the plasma excitation of this type. On the plasma-facing secondary side of these transformer arrangements, a plurality of plasma signals CT4a, CT4b, CT4n can be detected, in particular one and/or more plasma voltages. These can also be transmitted to the data connection 13 via the data bus 16.

At least one plasma generator 17a is connected to a power output connection 3a of the power supply arrangement 10 via an impedance matching apparatus 15a. In the present exemplary embodiment, all plasma generators 17a, 17b, . . . 17n are each equipped with an impedance matching apparatus 15a, 15b, . . . 15n each with a power output connection 3a, 3b, . . . 3n of the power supply arrangement 10.

The impedance matching apparatuses 15a, 15b, . . . 15n have, for example, a plurality of switchable inductors L1a, L2a, L3a, L1b, L2b, L3b, L1n, L2n, L3n. These are provided connectably in particular parallel to the connecting lines between the plasma generator 17a, 17b, . . . 17n and the power output connection 3a, 3b, . . . 3n of the power supply arrangement 10. This allows the impedance matching to be carried out very quickly in stages. The current through these inductors L1a, L2a, L3a, L1b, L2b, L3b, L1n, L2n, L3n can be determined with measurement sensors CT2a, CT2b, . . . . CT2n. These determined signals can also be fed to the data bus 16.

The impedance matching apparatuses 15a, 15b, . . . 15n each have a capacitor C1a, C1b, . . . C1n, for example. In particular, the latter can be a settable capacitor, e.g. by means of an adjustable vacuum capacitor. The capacitors can, as shown here, be provided in series between the plasma generator 17a, 17b, . . . 17n and the power output connection 3a, 3b, . . . 3n of the power supply arrangement 10. This allows the impedance matching to be performed very reliably.

A further inductor L4a, L4b, L4n can also, as shown here, be provided in series between the plasma generator 17a, 17b, . . . 17n and the power output connection 3a, 3b, . . . 3n of the power supply arrangement 10. This can be realized at least partially by the scattering inductance of the transformer arrangements T1a, T1b, T1n.

At the output or within the impedance matching apparatuses 15a, 15b, . . . 15n, further measurement sensors CT4a, CT4b, CT4n may be provided, which are suitable for detecting current, voltage, phase, impedance, and/or power. These detected signals can also be fed to the data bus 16.

The power supply arrangement 10 comprises a power input connection 2 for connection to an electrical supply power 7.

The power supply arrangement 10 further comprises a first power converter stage 5, which is configured to convert the input power at the power input connection 2 into an intermediate power, preferably a DC link power 12. A plurality of first power converter stages 5 for converting the input power at the power input connection 2 into an intermediate power, preferably into link power 12, can also be part of the power supply arrangement 10 and preferably be connected in parallel.

The power supply arrangement 10 further comprises, in particular, an AC generator stage 6, which is downstream of the first power converter stage 5 and is configured to convert the intermediate power from the first power converter stage into a bipolar output power.

Between the power converter stage 5 and the further AC generator stage 6, in particular an energy storage element, such as an inductor or a capacitor, for smoothing the current or the voltage, can be implemented.

The power supply arrangement 10 further comprises a plurality of switching units 8a, 8b, . . . 8n arranged here, for example, between the AC generator stage 6 and the power output connections 3a, 3b, . . . 3n.

One or more switching units may also be arranged outside the power supply arrangement 10, in particular in the vicinity, immediately before or after, or internally in one of the impedance matching apparatuses 15a, 15b, . . . 15n (not shown). Since the data bus 16 already has a connection outside the power supply arrangement 10, driving the switching units is also possible outside the power supply arrangement 10.

The power supply arrangement 10 further comprises a controller 4, which is configured to set the power supply arrangement 10 for supplying the bipolar output power to the power output connections 3a, 3b, 3n using at least one of the following control parameters: power, voltage, current, excitation frequency or threshold value for protective measures, so that at least one of the control parameters at a first power output connection 3a differs from the corresponding control parameter at another power output connection 3b, . . . 3n.

In this example, the controller 4 has connections to the power converter stages 5 and the switching units 8a, 8b, . . . 8n. Some of these connections may be optional, such as the connection to the power converter stage 5. The controller 4 can be configured such that it switches a switching unit 8a, 8b, . . . 8n from a closed state to an open state only if the absolute value of the current through the switch is less than one ampere, preferably zero. This has the advantage that switching units 8a, 8b, . . . 8n which do not need to be designed for switching higher currents can be used. This makes the device even cheaper.

The plasma generating device 1 may comprise a controller outside the power supply arrangement 10. This external controller can also control the plasma process in the loads 9a, 9b, . . . 9n.

The controller 4 may also be configured such that it switches a switching unit 8a, 8b, . . . 8n from an open state to a closed state only if the absolute value of the voltage along the open switch is less than 20 volts, preferably zero. This has the advantage that a switching unit that does not have to be designed for switching higher voltages can be used. This makes the device even cheaper.

The power supply arrangement 10 is capable of converting an electrical input power into a bipolar output power and supplying this output power to at least two independent loads 9a, 9b, . . . 9n, with the power supply arrangement comprising the following:
a power input connection 2 for connection to an electrical supply power 7,
at least two, preferably more than two, power output connections 31, 3b, . . . 3n, each for connection to one of the loads 9a, 9b, . . . 9n,
a controller 4 configured to control the power supply arrangement to supply the bipolar output power to the power output connections, using at least one of the following control parameters: power, voltage, current, excitation frequency, or threshold value for protective measures by obtaining a full set of target values for the parameters of the power output connections, wherein the controller 4 in particular is further designed to calculate whether the power supply arrangement is capable of supplying any target value to each power output connection, and, if this is the case, to calculate a sequence of pulses for supplying the power to the power output connections in order to provide the power for the plasma process.

In a further aspect, the controller 4 may be configured to control the power supply arrangement 10 such that at least one of the control parameters at a first power output connection 3a, 3b, . . . 3n is not equal to the corresponding control parameter of another power output connection. This allows the use of a single power supply arrangement with a given maximum power instead of using a plurality of power supply arrangements.

In this disclosure, ‘bipolar output power’ refers to an output power with an alternating current where the current changes its direction at a frequency that can excite the plasma process (excitation frequency).

Regulating parameters can be measured values or target values of the specified parameters.

The measured and target values can be an absolute value, instantaneous value, effective value such as an RMS (root mean square) value, or extreme value (such as maximum or minimum value).

The input power can be an electrical power supplied from an AC grid. It can also be a DC power line (AC: alternating current; DC: direct current).

The controller 4 may consist of a microcontroller running a software program when the power supply arrangement is in operation.

The controller 4 can have a plurality of interfaces, such as data links to external components, monitors, keyboards that can be wired or wirelessly connected.

The controller can have a computing part and a memory part. The memory part can be divided for various purposes, e.g. as monitor memory, RAM, data memory, program memory.

A threshold value can be a value used to detect ignition or collapse of the plasma. It can be set differently for each output port and change over time.

The bipolar output power can be a power value of more than 1 kW, preferably more than 10 kW.

The bipolar output power may have a frequency of more than 1 kHz, preferably more than 10 kHz, preferably more than 50 kHz.

In a further aspect, the power supply arrangement 10 may comprise a power converter stage 5, which is configured to convert the input power into an intermediate power, preferably into a DC link power.

In a further aspect, the power supply arrangement may comprise at least one AC generator stage 6, which is configured to convert the intermediate power from the first power converter stage 5 into the bipolar output power.

In a further aspect, the power supply arrangement 10 may comprise at least two further AC generator stages 6a, 6b, . . . 6n, which are configured to convert the intermediate power from the first power converter stage 5 into a plurality of bipolar output power signals and to carry these powers to the power output connections.

In a further aspect, the controller 4 may be configured to control the power converter stage 5 and/or AC generator stages 6, 6a, 6b, . . . 6n such that, during use, the power supply arrangement 10 at a first time provides a first power output signal in particular at a first power output connection for a first time frame and at a second time a second power output signal in particular at a second power output connection for a second time frame, with the first time being different from the second time and/or the first time frame being different from the second time frame.

In a further aspect, the power supply arrangement may comprise one or more switching unit(s) 8a, 8b, . . . 8n between the power converter stage(s) and the power output connections 3a, 3b, . . . 3n.

In a further aspect, the switching units 8a, 8b, . . . 8n are controlled by the controller 4.

In a further aspect, the controller 4 may be configured to control the power converter stage 5 and/or AC generator stages 6, 6a, 6b, . . . 6n and/or the switching units 8a, 8b, . . . 8n in such a way that the power supply arrangement during operation at a first time provides a first output power signal to the first power output connection for a first time frame and at a second time a second power signal to the second power output connection for a second time frame, with the first time being different from the second time and/or the first time frame being different from the second time frame.

In a further aspect, the switching units 8a, 8b, . . . 8n are configured in such a way that they can carry current in two opposite directions.

In a further aspect, the controller 4 may be configured such that it switches a switching unit 8a, 8b, . . . 8n from a closed state to an open state only if the absolute value of the current through the switch is less than one ampere, preferably zero.

In a further aspect, the controller 4 may be configured to activate a switching unit from an open state to a closed state only if the absolute value of the voltage along the open switch is less than 20 volts, preferably zero.

In a further aspect, at least one of the power converter stage 5 and/or AC generator stages 6, 6a, 6b, . . . 6n comprises a bridge circuit, preferably a full bridge circuit.

A bridge circuit can be a rectifier bridge circuit capable of rectifying AC power.

A bridge circuit can be a bipolar output-power-generating switching bridge circuit.

In a further aspect, the power supply arrangement 10 may comprise a housing that encloses all other parts of the unit.

In a further aspect, the input connections can be directly connected to the control cabinet.

In a further aspect, the power output connections 3a, 3b, . . . 3n can be directly connected to the housing.

In a further aspect, a plasma processing device 1 may comprise:
two, preferably more than two, loads 9a, 9b, . . . 9n,
an electrical power supply arrangement 10 as described above.

Each load 9a, 9b, . . . 9n can be connected to one of the power output connections 3a, 3b, . . . 3n of the power supply arrangement.

According to embodiments of the invention, a controller 4 is provided for controlling a plurality of plasma processes in a plurality of loads by converting an electrical input power into a bipolar output power and supplying this output power to the loads, wherein the controller is designed to control a power supply arrangement to supply the bipolar output power to the power outputs, using at least one of the following control parameters:
power, voltage, current, excitation frequency or threshold value for protective measures by obtaining a full set of target values for the parameters of the power output connections, the controller further being designed to calculate whether the power supply arrangement is capable of supplying any target value to each power output connection, and, if this is the case, to calculate a sequence of pulses for supplying the power to the power output connections to provide the power for the plasma process.

In a further embodiment of the controller 4, the complete set of target values can be provided by an interface link, preferably of a controller outside the power supply arrangement, wherein the external controller also controls the plasma process in the plasma chambers.

In a further embodiment of the controller 4, the calculation may include the determination of the maximum target power at all times and the comparison with the maximum power of the power supply arrangement.

In a further embodiment of the controller 4, an error message can be provided if the result of the calculation shows that there is no possibility of supplying the power of the target value to each power output connection.

In a further embodiment of the controller 4, one or more possibilities for changing the process with a new set of target values may be provided for the event that the result of the calculation is that there is no possibility of supplying the power of the target value to each power output connection.

In a further embodiment of the controller 4, the controller can control the power supply arrangement such that at least one control parameter of a first plasma chamber is not equal to a corresponding control parameter of another plasma chamber.

The plasma processes in the different loads 9a, 9b, . . . 9n can be different or the same. They can be the same, but in a different state, i.e. the plasma process in a first load is, for example, in a first gas excitation state, while the plasma process in a different load is initially in the gas conversion state.

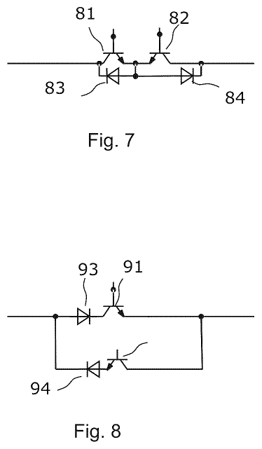

For the switching units 8a, 8b, . . . 8n, bipolar transistors 81, 82, 91, 92 can be used, as shown in FIGS. 7 and 8. These bipolar transistors are much cheaper than MOSFETs. The bipolar transistors 81, 82, 91, 92 can be IGBTs, which are low-cost transistors that carry high currents with low energy loss. This makes the power supply arrangement 1 even cheaper, as no expensive cooling devices are required.

In FIGS. 7 and 8, additional diodes 83, 84, 93, 94 are connected for carrying current in the desired direction and for blocking current in the undesirable direction.

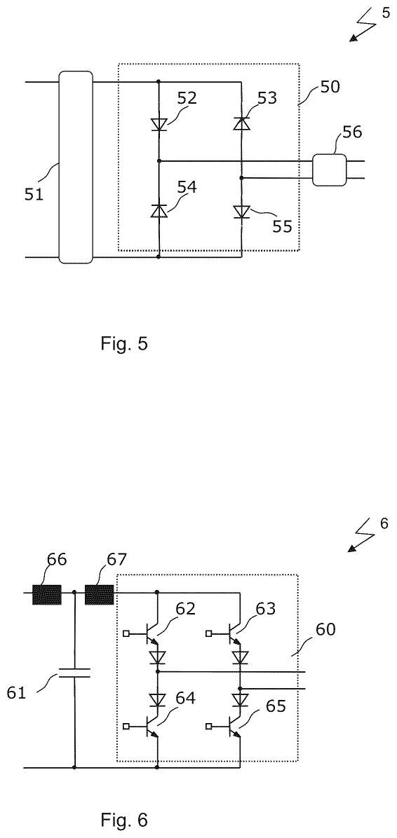

The power converter stage 5 may comprise a rectifier circuit, preferably a rectifier bridge circuit 50, as shown in FIG. 5. Four rectifier diodes 52, 53, 54, 55 are connected in a bridge circuit to rectify the alternating current from the first connection 51 to the second connection 56. At least one of the following elements can also be connected to the first connection 51: a filter, an overvoltage protection circuit, an overcurrent protection circuit. A filter can consist of one or more energy-storing elements such as capacitors or inductors.

The AC generator stage 6 can comprise a switching bridge, preferably a full bridge circuit 60, as shown in FIG. 6. This full bridge circuit 60 comprises four switching units 62, 63, 64, 65. These switching units can be transistors, bipolar transistors, IGBTs and, especially, MOSFETs. At the input of the second AC generator stage 6, a filter circuit with one or more energy storage elements such as a capacitor 61 and/or inductors 66, 67 can be located. The full bridge circuit 60 may further comprise a few diodes in the manner shown.

The power supply arrangement 10 may comprise a housing that encloses all other parts of the power supply arrangement 10. It can be made of metal, providing good protection against electromagnetic interference waves. The power input connection 2 can be directly connected to the housing. The power output connections 3a, 3b, . . . 3n can also be connected directly to the housing 10.

In a power supply arrangement 10, the current-carrying capability of all switching units 8a, 8b . . . 8n together can be higher than the maximum current supply capabilities of the power converter stage 5.

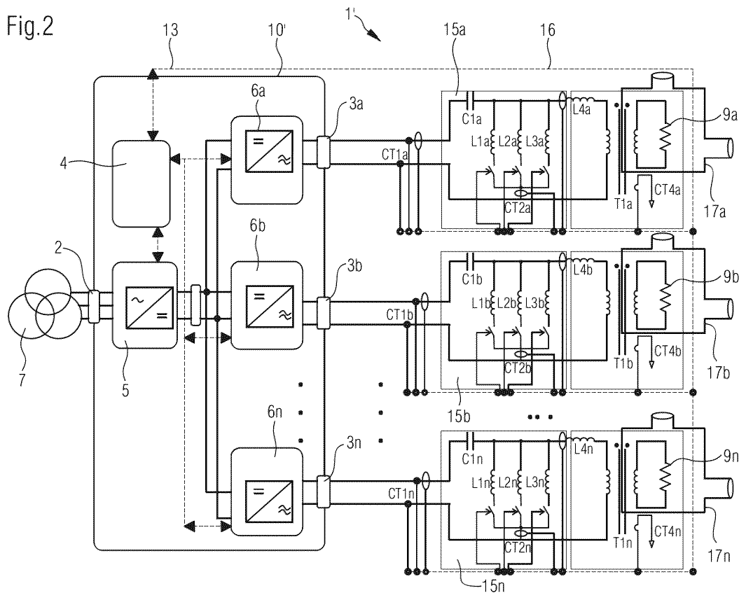

FIG. 2 shows a second plasma generating device 1′ with a second power supply arrangement 10′. The second power supply arrangement 10′ is an alternative to the first power supply arrangement 10 as shown in FIG. 1. All elements that match those in FIG. 1 have the same reference signs. The power supply arrangement 10′ shown in FIG. 2 contains instead of the switching unit(s) 8a, 8b, . . . 8n a plurality of power converter stages 6a, 6b, . . . 6n, which are configured to convert the DC intermediate power 12 from the first power converter stage 5 into a plurality of bipolar output power signals and to carry these powers to the power output connections 3a, 3b, . . . 3n. All power converter stages 6a, 6b, . . . 6n can be controlled by the controller 4. All power converter stages 6a, 6b, . . . 6n can consist of full bridges 60 and filter elements 61, 66, 67, as shown in FIG. 6.

At the power output connections 3a, 3b, . . . 3n, measurement sensors CT1a, CT1b, CT1n can be connected to measure voltage, current, frequency or power. The power supply arrangement 1 may also include a plurality of power converter stages 5, which are configured for converting the input power at the power input connection 2 into an intermediate power, preferably into DC link power 12, and are preferably connected in parallel.

The connecting lines for transmitting the AC power between the power supply arrangement 10 and one or more impedance matching apparatuses 15a, 15b, . . . 15n may have a length of 1 m or more, in particular 3 m or more. These cables may in particular have a specified impedance, which can preferably be a real impedance without imaginary part and can be preferably in the range of 45 to 80Ω. In such cases, one or more impedance matching apparatus(es) 15a, 15b, . . . 15n and the control signal(s) therefor are helpful.

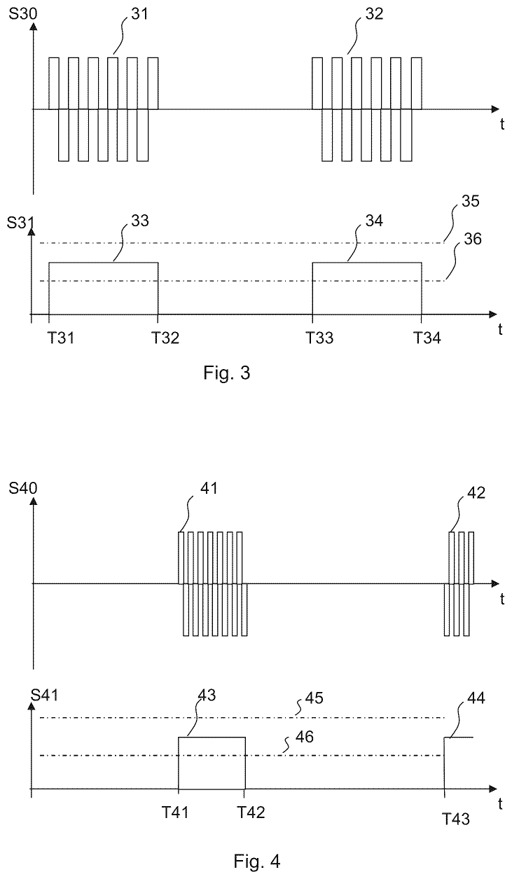

FIG. 3 shows a time diagram of the output power at a first power output connection 3a. The axis t is the time axis and the axis S30 can be, for example, the voltage, current or power axis. While the axis S30 represents the actual values of these parameters, the axis S31 represents an effective value of these parameters. In the first diagram of FIG. 3 with the axis S30, the bipolar signal is shown in two signal sequences 31, 32. The signal sequence 31 has an excitation frequency with a period of 2/11 of the time window that begins at time T31 and ends at time T32. The signal sequence 32 has an excitation frequency with a period of 2/11 of the time window that begins at time T33 and ends at time T34. In this example, these frequencies are the same, but it is possible that these frequencies may be different. In the second diagram of FIG. 3 with the axis S31, the effective values of the two signal sequences 31, 32 are shown in two signal sequences 33, 34. Two threshold value lines 35, 36 are also drawn in this diagram. They can be used to detect a plasma collapse, such as an arc or ignition of the plasma, if the effective value of any of the parameters power, voltage or current exceeds such a threshold.

In a power supply arrangement 1′, the current-carrying capability of all power converter stages 6a, 6b, . . . 6n together may be higher than the maximum current supply capabilities of all power converter stages 5 together.

FIG. 4 shows a time diagram of the output power at another power output connection 3b, . . . 3n. The axis t is the time axis and the axis S40 can be, for example, the voltage, current or power axis. While the axis S40 represents the actual values of these parameters, the axis S41 represents an effective value of these parameters. In the first diagram of FIG. 4 with the axis S40, the bipolar signal is shown in two signal sequences 41, 42. The signal sequence 41 has an excitation frequency with a period of 1/7 of the time window that begins at time T41 and ends at time T42. At time T43, a second pulse 44 begins, the end of which is not shown in this diagram. At time T43, the second signal sequence 42 begins. From this example it can be seen that the frequencies of the signal sequences 31, 32 and of the signal sequences 41, 42 are different, with the frequency of the signal sequences 41, 42 being higher than the frequency of the signal sequences 31, 32.

In addition to or as an alternative to excitation at different frequencies, the power, voltage, current, or threshold value for protective measures between two different power output connections 3a, 3b, . . . 3n or at two different loads 9a, 9b, . . . 9n can also be different.

This diagram also shows two threshold value lines 45, 46. They can be used to detect a plasma collapse, such as an arc or ignition of the plasma, if the effective value of any of the parameters power, voltage, or current exceeds such a threshold value.

Embodiments of the invention work in such a way that it controls a plurality of plasma processes in the plurality of loads 9a, 9b, . . . 9n with the controller 4 by converting an electrical input power into a bipolar output power, as shown in the signal sequences 31, 32, 41, 42, and supplying this output power to the loads 9a, 9b, . . . 9n. The controller 4 controls the power supply arrangement 1 for supplying the bipolar output power to the power output connections 3a, 3b, . . . 3n using at least one of the following control parameters: power, voltage, current, excitation frequency or threshold value for protective measures by obtaining a full set of target values for the parameters of the power output connections 3a, 3b, . . . 3n, the controller 4 further being designed to calculate whether the power supply arrangement 1,1′ is capable of supplying any target value to each power output connection 3a, 3b, . . . 3n, and, if this is the case, to calculate a sequence of pulses for supplying the power to the power output connections 3a, 3b, 3n to provide the power for the plasma process.

For this purpose, the controller 4 may control the power converter stages 6, 6a, 6b, . . . 6n or the switching units 8a, 8b, . . . 8n in such a way that the unit 1 during operation at a first time T31 provides a first output power signal to the first power output connection 3a for a first time frame T31-T32 and at a second time T41 a second power signal to a second power output connection 3b, . . . 3n for a second time frame T41-T42, with the first time T31, T41 being different from the second time T32, T42 and/or the first time frame T31-T32 being different from the second time frame T41-T42.

A plasma generating device 1 as shown in FIG. 1 and a plasma generating device 1′ as shown in FIG. 2 impose restrictions on the simultaneous operation of more than one power output connection 3a, 3b, . . . 3n. For plasma generating devices 1′ as shown in FIG. 2, these restrictions arise if, for example, the total power or processing capacity of the output stage connected to an input stage exceeds the power or the instantaneous capacity of this input stage, so that the maximum output power cannot be simultaneously provided at all power output connections 3a, 3b, . . . 3n. For plasma generating devices as in FIG. 1, the maximum output power can be provided only at one power output connection 3a, 3b, . . . 3n, or a part of the power at more than one power output connection 3a, 3b, . . . 3n. In the event that the independent operation of different plasma processes is necessary, this can be achieved as long as the total working cycle of all processes plus the time for switching between outputs is less than the total cycle time.

These restrictions define ranges where operation is possible and ranges where operation is not possible, in the scope of the above parameters. For any request in the power supply to provide power at an output or a set of power output connections 3a, 3b, . . . 3n, the location within or outside of the range in which operation is possible should be determined. This results in the need for a sequence control.

A sequence controller 14 can be part of the controller 4. The algorithm thereof determines for each request for the power supply arrangement 1, or for a request to change one or more parameters if the request is within the possible operating range, the output power to be supplied for each of the power output connections. For a process as shown in FIGS. 3 and 4, in which power is supplied to the power output connections 3a, 3b, . . . 3n, wherein the different power output connections 3a, 3b, . . . 3n are operated with different powers, with different pulse duty cycles or different pulse frequencies, the sequence control ensures that:
the pulse frequencies are integer multiples of each other to avoid pulse overlaps (for plasma devices 1′ as shown in FIG. 2)
for overlapping pulses, the total requested power and current does not exceed the possible maximum (for plasma devices 1′ as shown in FIG. 2)
if possible maxima are exceeded for a limited period of time in the cycle, a pattern without this exceeding is found (for plasma devices 1′ as shown in FIG. 2)
the sum of the pulses in time points plus the time for switching between outputs is less than the smallest pulse cycle frequency (for plasma devices 1 as in FIG. 1)
a newly requested output pulse pattern is activated at a specific output at a correct time to fit into existing pulse patterns of other outputs (for plasma devices 1 as shown in FIG. 1)
total average power limits and currents are not exceeded
a warning is issued to the user if the requested sequence is outside the possible range
a possible modified sequence is recommended to the user.

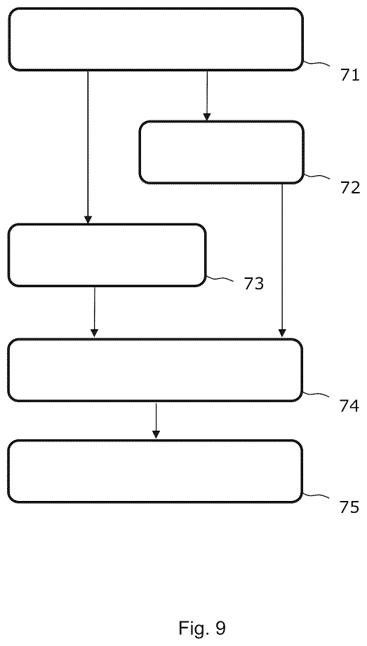

FIG. 9 shows a flowchart for a method sequence. The method may be characterized in particular by its suitability for controlling a plurality of plasma processes, which are in particular designed in each case to excite a gas spatially remote from a plasma processing to a gas plasma, that is, for controlling a plurality of so-called ‘remote plasma sources’ RPS, comprising the following steps:
Step 71: Supplying electrical supply power to a power supply arrangement 10
Step 72: Converting the electrical supply power into a first AC power and supplying the first AC power to a first load 9a of a first plasma generator 17a
Step 73: Converting the electrical supply power into a second AC power and supplying the second AC power to a second load 9b of a second plasma generator 17b, wherein steps 73 and 72 are not performed at the same time
Step 74: Controlling the AC powers according to different characteristics at one or more of the following control values:
output current,
output voltage,
output frequency,
output power,
output profile of current and/or voltage, and
Step 75: Generating and outputting a control signal for an impedance matching apparatus 15a, 15b, 15n, which is assigned to one of the AC powers.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A power supply arrangement for a plurality of plasma generators, each of the plurality of plasma generators being configured to excite a gas spatially remote from a plasma processing to a gas plasma, the power supply arrangement comprising:
a power input connection for connecting to a supply power,
a data connection for connecting to a controller, and
an AC generator stage configured to convert a power from the power input connection into an AC power,
wherein the power supply arrangement is configured to, via the data connection,
ensure that the AC power is able to be supplied to a first load as a first AC power and to a second load spatially remote from the first load as a second AC power, wherein the first load and the second load are not supplied simultaneously,
wherein the power supply arrangement is controllable in such a way that the first AC power and the second AC power have different characteristics at least in one or more of:
output current,
output voltage,
output frequency,
output power, or
output profile of current and/or voltage, and
wherein the power supply arrangement is configured to output a drive signal for an impedance matching apparatus assigned to one of the first AC power and the second AC power.

2. The power supply arrangement as claimed in claim 1, further comprising:
a first power output connection for supplying the first AC power to the first load, and
a second power output connection for supplying the second AC power to the second load spatially remote from the first load.

3. The power supply arrangement as claimed in claim 2, further comprising a switching unit, wherein the power supply arrangement is configured to ensure, via the data connection, that the switching unit connects the AC power generated by the AC generator stage to one of the first power output connection and the second power output connection, and/or to one of the first load and the second load.

4. The power supply arrangement as claimed in claim 1, wherein the power supply arrangement is configured such that a sum of all rated powers of the first AC power and the second AC power suppliable to the first load and the second load is greater than a rated power of the AC generator stage.

5. The power supply arrangement as claimed in claim 1, wherein the power supply arrangement is configured to output different control signals for a plurality of impedance matching apparatuses, each of the plurality of impedance matching apparatuses is assigned to one of the first AC power and the second AC power.

6. The power supply arrangement as claimed in claim 1, wherein the power supply arrangement is configured to receive one or more plasma signals from one of the plurality of plasma generators.

7. The power supply arrangement as claimed in claim 6, wherein the power supply arrangement is configured to assign one or more of the plasma signals to the characteristics of the first AC power and the second AC power based on the respective plasma signals.

8. The power supply arrangement as claimed in claim 1, wherein the power supply arrangement is configured to receive one and/or more voltages and/or currents from a current measurement sensor and/or a voltage measurement sensor, wherein the current measurement sensor or the voltage measurement sensor is arranged and configured to measure a current and/or a voltage of the AC power, and wherein the power supply arrangement is further configured to assign the one or more voltages and/or currents to the characteristics of the first AC power and the second AC power based on the respective voltages and/or currents.

9. The power supply arrangement as claimed in claim 1, wherein the power supply arrangement is configured to receive one and/or more voltages and/or currents from a current measurement sensor and/or a voltage measurement sensor, wherein the current measurement sensor or the voltage measurement sensor is arranged and configured to measure a current and/or a voltage at an impedance matching apparatus, and wherein the power supply arrangement is further configured to assign the one or more voltages and/or currents to the characteristics of the first AC power and the second AC power based on the respective voltages and/or currents.

10. The power supply arrangement as claimed in claim 1, wherein the controller is integrated in the power supply arrangement.

11. A plasma generating device, comprising:
a power supply arrangement as claimed in claim 1 and
a plurality of plasma generators connected to the power supply arrangement, wherein the plurality of plasma generators is operated according to the characteristics of the first AC power and the second AC power.

12. The plasma generating device as claimed in claim 11, further comprising a transformer arrangement for each plasma generator of the plurality of plasma generators, for coupling the first AC power or the second AC power to the first load or the second load, wherein the transformer arrangement is arranged in an immediate vicinity of the first load or the second load.

13. The plasma generation device as claimed in claim 11, further comprising a plurality of impedance matching apparatuses, wherein each respective impedance matching apparatus is arranged between the power supply arrangement and a respective plasma generator.

14. The plasma generating device as claimed in claim 11, wherein the plurality of plasma generators is configured to excite a gas spatially remote from a plasma processing to a gas plasma.

15. A method for controlling a plurality of plasma processes, each of plurality of plasma processes is configured to excite a gas spatially remote from a plasma processing to a gas plasma, the method comprising:
supplying an electrical supply power to a power supply arrangement,
converting the electrical supply power into a first AC power and supplying the first AC power to a first load of a first plasma generator,
converting the electrical supply power into a second AC power and supplying the second AC power to a second load of a second plasma generator,
wherein in the first AC power and the second AC power are not supplied at the same time,
controlling the first AC power and the second AC power according to different characteristics in one or more of:
output current,
output voltage,
output frequency,
output power, or
output profile of current and/or voltage, and
generating and outputting a drive signal for an impedance matching apparatus assigned to one of the first AC power and the second AC power.
